(19) United States
(12) Patent Application Publication
(10) Pub. No.: US 2025/0081339 A1
(43) Pub. Date: Mar. 6, 2025

(54) MULTI-LAYER ELECTRICAL STRUCTURES

(71) Applicant: Qorvo US, Inc., Greensboro, NC (US)

(72) Inventors: Jerry Holt, Hillsborough, NC (US); Kelly M. Lear, Longwood, FL (US); Lawrence A. Carastro, Windermere, FL (US); Byron Bullis, Graham, NC (US)

(21) Appl. No.: 18/811,963

(22) Filed: Aug. 22, 2024

Related U.S. Application Data
(60) Provisional application No. 63/580,795, filed on Sep. 6, 2023.

(51) Int. Cl. H05K 1/02; H05K 1/18; H05K 3/46

(52) U.S. Cl. CPC H05K 1/0298; H05K 1/025; H05K 1/185; H05K 3/4652

(57) ABSTRACT

Multi-layer electrical structures are disclosed. In one aspect, an electrical structure in a multi-layer structure such as a metalized laminate is stacked such that multiple electrical structures can be provided in the same footprint. In particular aspects, the multiple electrical structures are identical and placed electrically in parallel with one another to assist in creating a desired impedance. In still further particular aspects, the multiple electrical structures are couplers used to split or combine a signal for an amplifier chain or other circuits in a transceiver. This arrangement provides a desired low impedance at a small footprint and may assist in providing more efficient impedance transformations in the amplifier chain.

### RELATED APPLICATION

This application claims the benefit of U.S. Provisional Patent Application Ser. No. 63/580,795 filed on Sep. 6, 2023, and entitled “STACKED LAND GRID ARRAY MODULES,” the contents of which are incorporated herein by reference in its entirety.

### BACKGROUND

### I. Field of the Disclosure

The technology of the disclosure relates generally to multi-layer structures with electrical devices therein, such as couplers.

### II. Background

Computing devices abound in modern society, and more particularly, supporting mobile communication devices has become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. Many such communication devices rely on amplifier chains to amplify signals for transmission. These signals are at increasingly higher frequencies and have correspondingly increased bandwidth. Concurrently, there is always commercial pressure to make the amplifier chains increasingly smaller. Finding a way to balance size constraints while also improving efficiencies in the amplifier chains provides room for innovation.

### SUMMARY

Aspects disclosed in the detailed description include multi-layer electrical structures and methods for forming same. In particular, aspects of the present disclosure contemplate forming an electrical structure in a multi-layer structure such as a metalized laminate, where a finalized package includes stacked metalized laminates such that multiple electrical structures can be provided in the same footprint. In particular aspects, the multiple electrical structures are identical and placed electrically in parallel with one another to assist in creating a desired impedance. In still further particular aspects, the multiple electrical structures are couplers (or transformers, splitters, time delay units, or the like) used to split or combine a signal for an amplifier chain or other circuits in a transceiver. This arrangement provides a desired low impedance at a small footprint and may assist in providing more efficient impedance transformations in the amplifier chain. In a further aspect, stacked dies may be formed having parallel structures according to aspects of the present disclosure.

In this regard, in one aspect, a circuit package is disclosed. The circuit package includes a first multi-layer structure comprising a first electrical structure spread across layers of the first multi-layer structure and one or more first exposed conductors on an exterior layer of the first multi-layer structure. The circuit package also includes a second multi-layer structure stacked on the first multi-layer structure, the second multi-layer structure comprising a second electrical structure spread across layers of the second multi-layer structure, and one or more second exposed conductors on an exterior layer of the second multi-layer structure. The circuit package further includes a conductive bonding agent coupling the one or more first exposed conductors to the one or more second exposed conductors such that the first electrical structure is electrically parallel to the first electrical structure and a material encapsulating the first multi-layer structure and the second multi-layer structure and flowing around the conductive bonding agent.

In another aspect, a communication device is disclosed. The communication device includes a transmit chain comprising: a baseband processor (BBP), a mid-level impedance matching circuit coupled to the BBP, the mid-level impedance matching circuit configured to lower an impedance of a signal line from the BBP to a lower impedance, and a package. The package of the communication device comprises a plurality of couplers electrically in parallel to provide an impedance matching the lower impedance, a second impedance matching circuit coupled to the plurality of couplers and configured to lower a package signal line impedance from the lower impedance to a lowest impedance; and a power amplifier coupled to the second impedance matching circuit, the power amplifier comprising an input with approximately the lowest impedance.

In another aspect, a method of making a package is disclosed. The method includes forming a multi-layer metalized laminate having a plurality of electrical structures formed across multiple layers of the multi-layer metalized laminate, singulating the multi-layer metalized laminate into sub-sheets, and stacking a first sub-sheet onto a second sub-sheet. The method also includes electrically coupling electrical structures in the first sub-sheet to electrical structures in the second sub-sheet in parallel, encapsulating the sub-sheets in a mold material, and singulating the sub-sheets into parallel structure packages.

### BRIEF DESCRIPTION OF THE DRAWINGS

FIG. 1A is an exploded view of a coupler in a laminate structure;

FIG. 1B is a top-plan view of the coupler of FIG. 1A without being exploded;

FIG. 2 is a block diagram of a two-amplifier structure with a coupler used at an input to split an incoming signal;

FIG. 3 is a block diagram of a two-amplifier structure with a mid-to-low impedance coupler positioned after an initial impedance-matching structure;

FIG. 4 is a block diagram of a way to implement a mid-to-low impedance coupler without increasing footprint using parallel couplers;

FIG. 5 is a cross-sectional side elevational view of an amplifier package using stacked laminates having parallel couplers;

FIG. 6 is a flowchart illustrating an exemplary process for forming stacked laminate electrical structures such as the couplers of FIG. 5;

FIG. 7A is an isometric view of a laminate formed as an intermediate product according to the process of FIG. 6;

FIGS. 7B and 7C are cross-sectional side elevational views of intermediate products formed using the process of FIG. 6;

FIG. 8 is a side elevational view of a stacked die aspect of the present disclosure;

FIG. 9 is a flowchart illustrating an exemplary process for forming the stacked die aspect of FIG. 8; and

FIG. 10 is a block diagram of a communication device, which may include the stacked laminate electrical structures according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first clement could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other clement or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include multi-layer electrical structures and methods for forming same. In particular, aspects of the present disclosure contemplate forming an electrical structure in a multi-layer structure such as a metalized laminate, where a finalized package includes stacked metalized laminates such that multiple electrical structures can be provided in the same footprint. In particular aspects, the multiple electrical structures are identical and placed electrically in parallel with one another to assist in creating a desired impedance. In still further particular aspects, the multiple electrical structures are couplers (or transformers, splitters, time delay units, or the like) used to split or combine a signal for an amplifier chain or other circuits in a transceiver. This arrangement provides a desired low impedance at a small footprint and may assist in providing more efficient impedance transformations in the amplifier chain.

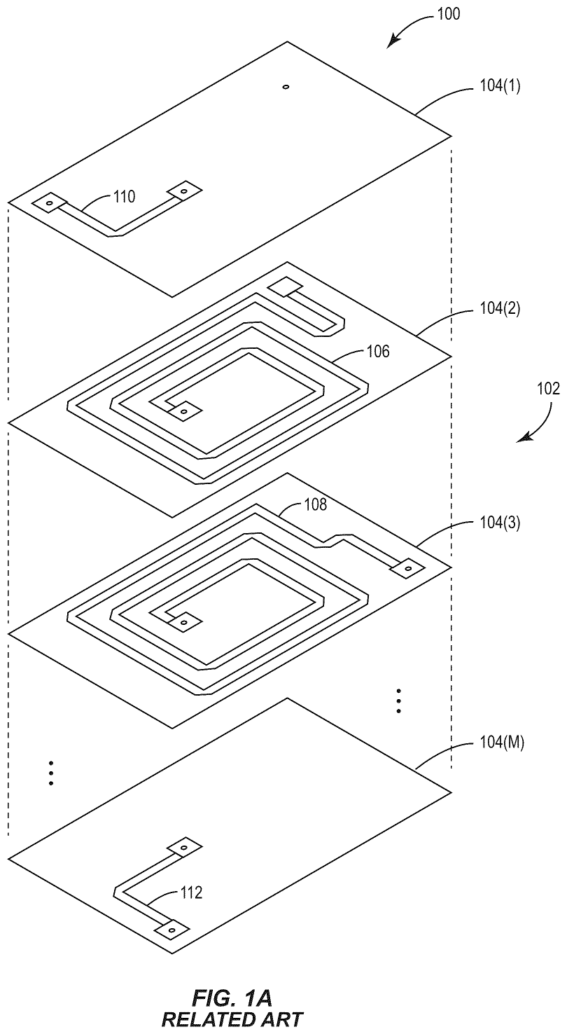

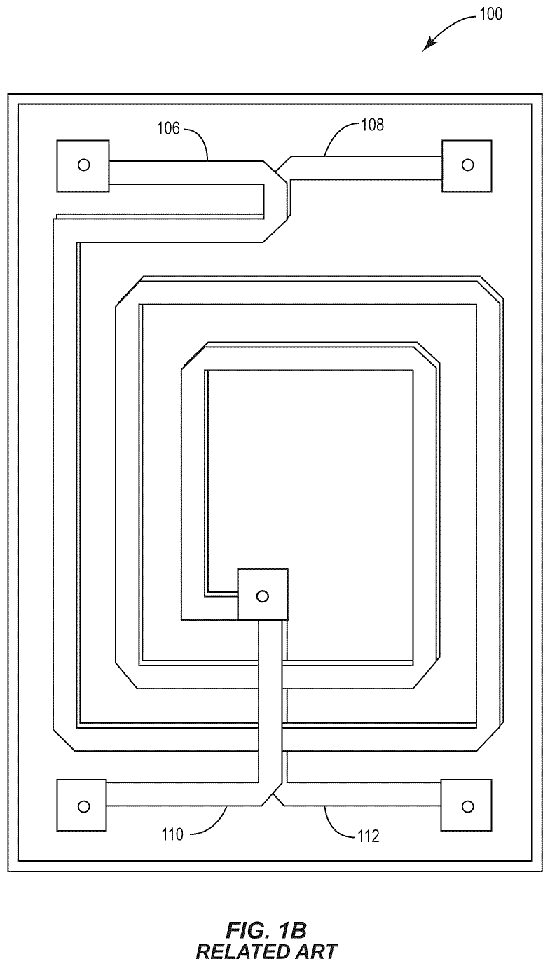

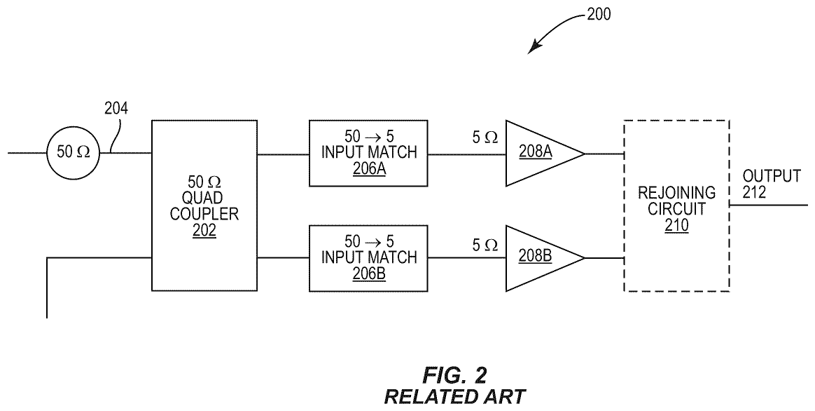

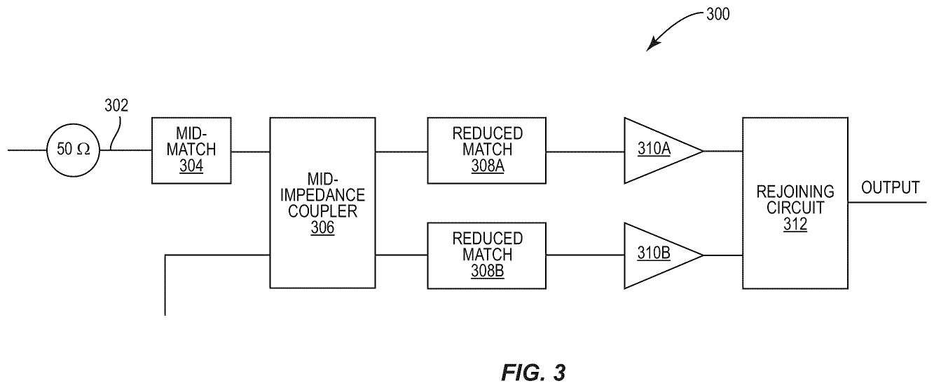

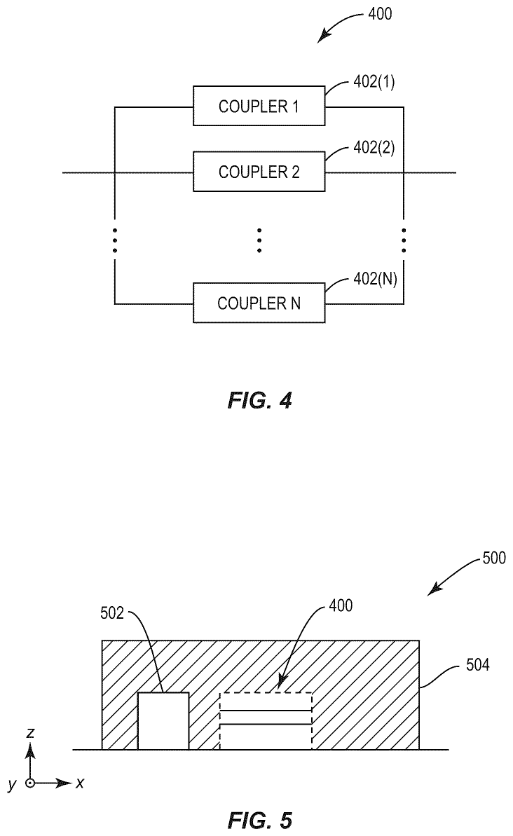

Before addressing aspects of the present disclosure, a brief overview of a coupler is provided with reference to FIGS. 1A and 1B, with FIG. 2 showing how such a coupler may be used in a two-amplifier structure, while FIG. 3 illustrates an amplifier chain with a more efficient coupler structure that requires a low impedance. A discussion of a coupler formed with the multi-layer electrical structures of the present disclosure begins below with reference to FIG. 4.

In this regard, FIG. 1A illustrates an exploded view of a metalized laminate 100 that has an electrical structure 102 formed from conductive elements spread across multiple layers 104(1)-104(M) of the metalized laminate 100. As illustrated, the electrical structure 102 is a coupler having a first spiraled conductor 106 on a layer 104(2) and a second spiraled conductor 108 on a layer 104(3). Vias (not shown) couple different ones of the multiple layers 104(1)-104 (M). Additional conductors 110, 112 may also be positioned on other layers 104(1), 104(M). While not shown, other layers within the layers 104(1)-104(M) may have ground planes or other conductive elements.

FIG. 1B shows a top-plan view of the coupler in the metalized laminate 100. It should be appreciated that the impedance of the coupler is a function, at least in part of the line width of the conductors 106, 108, 110, 112, where the wider the line width, the lower the impedance. Note also that increasing the line width also necessitates increasing the space between the lines. Thus, the overall footprint of two couplers with a 2:1 impedance ratio may be a 1:4 footprint ratio (that is, the smaller impedance footprint may be approximately four times larger than the larger impedance footprint). Given the commercial pressures to reduce component size, such an increase in footprint is unacceptable.

When the coupler is used in an amplifier chain 200 illustrated in FIG. 2, it may be permissible to have a high-impedance coupler 202. The amplifier chain 200 may be a two-amplifier topology, such as a Doherty amplifier, load-modulated balanced amplifier, push-pull amplifier, or the like. That is, a signal may come from a baseband processor (BBP, not shown) at a first impedance, typically fifty ohms at an input 204. The coupler 202 is also at a relatively high-impedance, such as 50 ohms, and splits the signal. The split signal is provided to two impedance-matching circuits 206A, 206B that lower the impedance to match the input impedances of amplifiers 208A, 208B. In an extreme but realistic example, the input impedances may be approximately five ohms. A rejoining circuit 210 recombines the signals to provide an amplified signal at an output 212. For example, for a Doherty amplifier, the rejoining circuit 210 may be a phase shifter for the main amplifier. Note that large impedance changes of this nature may limit the bandwidth of the amplifier chain 200. Further, the impedance-matching circuits 206A, 206B have to be high-Q, which increases costs.

One possible solution to the challenges of the impedance-matching circuits 206A, 206B is to spread the impedance matching across multiple stages, as better seen in amplifier chain 300 of FIG. 3. In the amplifier chain 300, a signal is provided to an input 302, and an initial impedance match is provided by mid-match circuit 304. In an exemplary aspect, the mid-match circuit 304 may transform the impedance from approximately fifty ohms to approximately 16-17 ohms. A mid-impedance coupler 306 may then split the signal but has a relatively low impedance of 16-17 ohms. The split signal is further impedance-matched by reduced impedance-matching circuits 308A, 308B and the signal is provided to amplifiers 310A, 310B before being rejoined by rejoining circuit 312.

The element that makes use of the mid-impedance coupler 306 attractive is also the source of the difficulty in using the mid-impedance coupler 306. That is, to get the desired mid-impedance, the coupler requires wide conductors, as explained above. These wide conductors increase the overall footprint of the coupler, making it commercially impractical.

Aspects of the present disclosure contemplate putting multiple couplers in parallel to reduce the effective impedance of the overall coupler structure as better illustrated in FIG. 4, where a coupler structure 400 may include N parallel couplers 402(1)-402(N). The parallel structure allows for the impedance to be reduced in a manner similar to parallel resistors.

While conceptually placing the couplers 402(1)-402(N) in parallel may seem simple, the implementation is non-trivial. That is, most metalized laminates are less than ten layers (i.e., M<10). When more than ten layers are used, current manufacturing techniques leave open the possibility of delamination or other issues, leading to reduced yields of greatly increased costs. Further, while only four layers are illustrated in FIG. 1A, a coupler may require six or more layers when ground planes and the like are considered. Thus, having two six-plus layer couplers in a single metalized laminate would push the total layer count above the reasonable maximum of ten layers.

Aspects of the present disclosure contemplate stacking multiple nearly identical metalized laminates on top of one another, thereby keeping the overall footprint relatively small. Note that while the metalized laminates may be nearly identical, it should be appreciated that some structures may need slight adjustments for increased electrical length of input/output conductors (e.g., the upper portions may be further away from a substrate than lower portions and may have longer input/output conductors). Further, while metalized laminates are specifically contemplated, other multi-layer structures are also possible such as for example, low-temperature co-fired ceramics (LTCC) structures, high-temperature co-fired ceramics (HTCC), additive manufacturing (e.g., 3D printing) structures, or the like. Note also that while using parallel structures to reduce impedance is well suited for use with couplers, the concept of using parallel electrical structures is readily extended to transformers, splitters, time delay units, or the like. For example, package 500 may include the coupler structure 400. It should be appreciated that a height (in the z-axis direction) of the coupler structure 400 may be less than a nearby surface-mounted element (e.g., an inductor or capacitor) 502. The coupler structure 400, the surface-mounted element 502, and an amplifier die (not shown) may be encapsulated in an overmold 504. Use of mold material to form the package 500 is well understood in the industry.

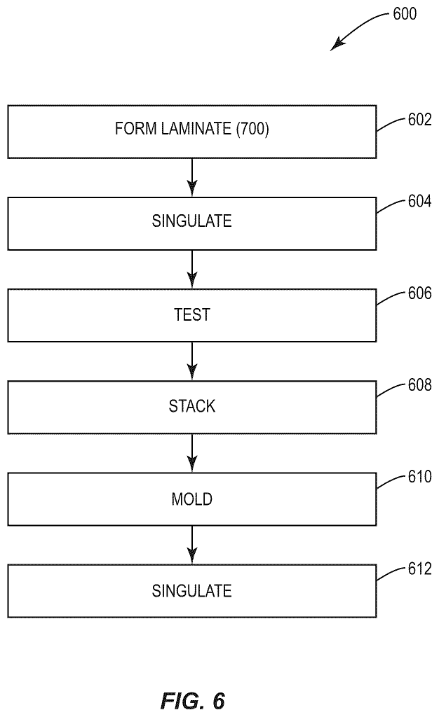

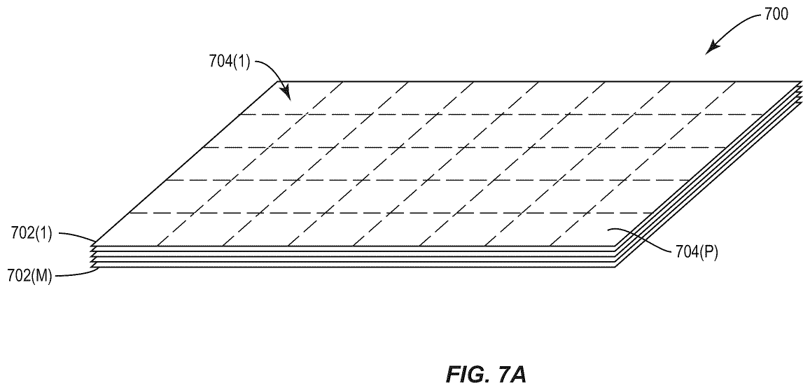

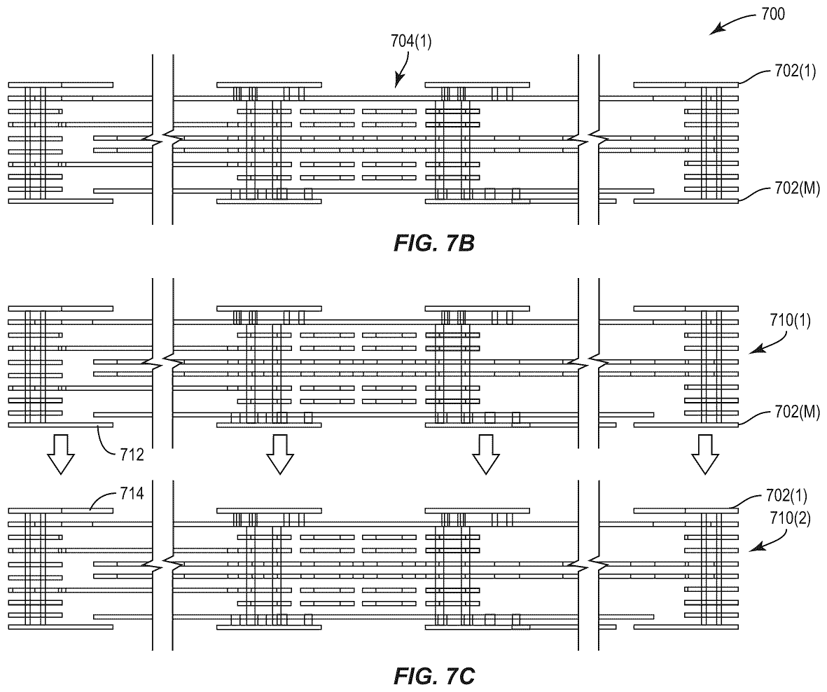

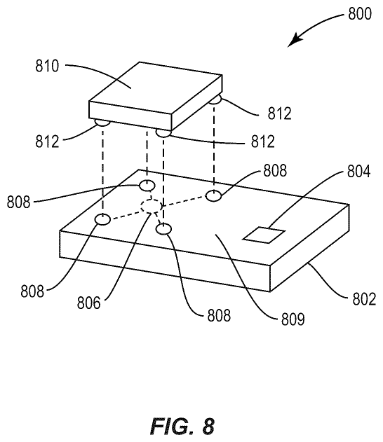

Aspects of the present disclosure provide a method 600 for forming the stack of parallel electrical structures in a metalized laminate with reference to FIG. 6 (although again, other multi-layer structures can be used (e.g., LTCC, HTCC, or additive manufacturing structures)). The process 600 begins by forming a laminate 700 (block 602, FIGS. 7A & 7B). The laminate 700 is a metalized laminate with multiple layers 702(1)-702(M), where the layers 702(1)-702(M) include conductors and are interconnected with vias. In an exemplary aspect, the number M of layers 702(1)-702(M) is less than twelve. The conductors on these layers collectively form an electrical structure such as a coupler. More specifically, the laminate 700 is actually a large sheet with multiple discrete electrical structures 704(1)-704(P).

The process 600 continues by singulating the laminate 700 into sub-sheets 710(1)-710(2) (although more may be formed) (block 604). The sub-sheets are identically sized. Exterior layers 702(1) and 702(M) may have exposed conductors that are treated and/or conditioned to accept a solder material, although other conductive bonding agents (e.g., a silver conductive epoxy) may be used. The electrical structures 704(1)-704(P) may then be tested (block 606) for process variations, functionality, or the like using one more of the contacts/exposed conductors on the exterior layers 702(1), 702(M).

The sub-sheets 710(1)-710(2) are then stacked (block 608, FIG. 7C) and coupled to one another. That is, solder or other conductive bonding agents may be applied between exposed conductors 712, 714 of a layer 702(1) and a layer 702(M) of the different sub-sheets 710(1)-710(2). There may be a reflow and a wash, as is well understood. The solder will secure the sub-sheets 710(1)-710(2) to one another. A mold material may then be applied (block 610) and flow between and around the solder points. Note that instead of mold, an air cavity may be formed instead. The joined sub-sheets 710(1)-710(2) may then be singulated again (block 712) into single-stacked electrical structures. While only two are shown in FIG. 7C, it should be appreciated that additional stacking may be performed without departing from the present disclosure. Likewise, the stacked parallel electrical structures may then be incorporated into a larger package (i.e., with a power amplifier or other elements and another mold material be applied to encapsulate the entire larger package.

While the above discussion has focused on the possibility of stacking laminates, the present disclosure is not so limited. Thus, for example, dies may be stacked with parallel couplers in different dies. An exemplary stacked die package 800 is illustrated in FIG. 8. A first die 802 may include various elements such as a power amplifier 804 and also a first coupler 806. Connective elements 808 lie on a surface 809 or extend above it to allow an electrical connection to the first coupler 806.

A second die 810 is positioned in a flip-chip arrangement relative to the first die 802. A second coupler (not shown) may be positioned within the second die 810. The second die 810 includes connective elements 812 that are aligned with the connective elements 808 and may be heated to reflow together. This arrangement allows the first coupler 806 and the second coupler to be in parallel with one another electrically.

As shown, the second die 810 is smaller than the first die 802, but other arrangements could also be made.

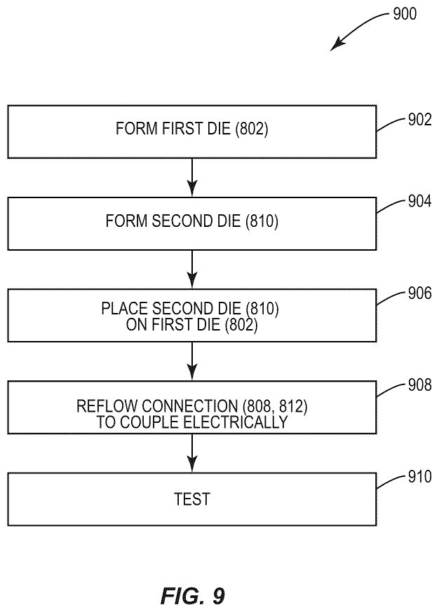

FIG. 9 is a flowchart of a process 900 for forming the stacked die package 800. The process 900 begins by forming a first die 802 (block 902) and the second die 810 (block 904). The second die 810 is placed on the first die 802 (block 906) e.g., by pick and place technology. The placement aligns the connections 808, 812. The connections 808, 812 are then reflowed (block 908) or otherwise coupled to one another electrically. The package 800 may then be tested (block 910).

The stacked laminate electrical structures, according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter. Note that there may be non-processor-based solutions that can benefit from aspects of the present disclosure (e.g., a dumb wireless transceiver with no real processor-based control circuit).

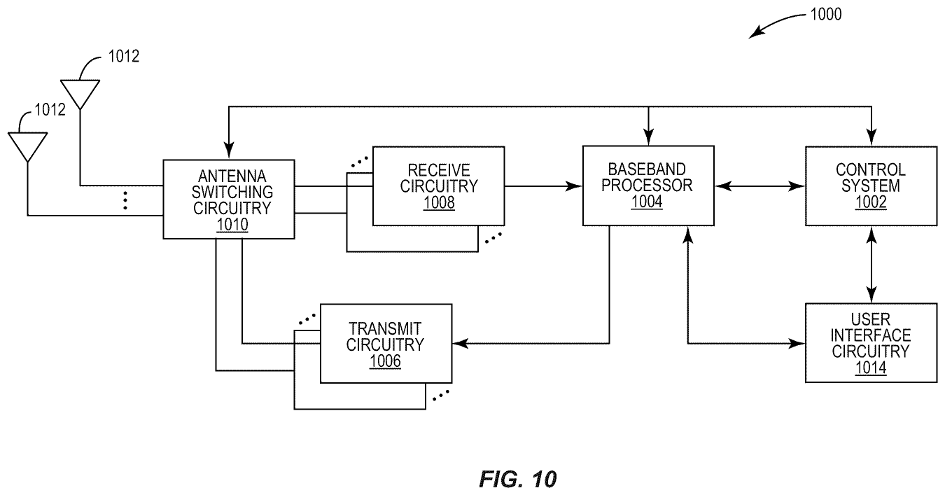

FIG. 10 is a schematic diagram of an exemplary communication device 1000 wherein the stacked laminate electrical structures of the present disclosure can be provided. Herein, the communication device 1000 can be any type of communication device, such as those listed above, as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 1000 will generally include a control system 1002, a baseband processor 1004, transmit circuitry 1006, receive circuitry 1008, antenna switching circuitry 1010, multiple antennas 1012, and user interface circuitry 1014. In a non-limiting example, the control system 1002 can be a field-programmable gate array (FPGA) or an application-specific integrated circuit (ASIC), as an example. In this regard, the control system 1002 can include at least a microprocessor(s), an embedded memory circuit(s), and a communication bus interface(s). The receive circuitry 1008 receives radio frequency signals via the antennas 1012 and through the antenna switching circuitry 1010 from one or more base stations. A low noise amplifier and a filter of the receive circuitry 1008 cooperate to amplify and remove broadband interference from the received signal for processing. This low noise amplifier may be an amplifier chain that uses a stacked parallel coupler, for example, according to aspects of the present disclosure. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1004 processes the digitized received signal to extract the information or data bits conveyed in the received signal. This processing typically comprises demodulation, decoding, and error correction operations. The baseband processor 1004 is generally implemented in one or more digital signal processors (DSPs) and ASICs.

For transmission, the baseband processor 1004 receives digitized data, which may represent voice, data, or control information, from the control system 1002, which it encodes for transmission. The encoded data is output to the transmit circuitry 1006, where a digital-to-analog converter(s) (DAC) converts the digitally encoded data into an analog signal, and a modulator modulates the analog signal onto a carrier signal that is at a desired transmit frequency or frequencies. A power amplifier, which may, for example, include a stacked parallel coupler according to aspects of the present disclosure, will amplify the modulated carrier signal to a level appropriate for transmission and deliver the modulated carrier signal to the antennas 1012 through the antenna switching circuitry 1010 to the antennas 1012. The multiple antennas 1012 and the replicated transmit and receive circuitries 1006, 1008 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A circuit package comprising:
a first multi-layer structure comprising:
a first electrical structure spread across layers of the first multi-layer structure; and
one or more first exposed conductors on an exterior layer of the first multi-layer structure;
a second multi-layer structure stacked on the first multi-layer structure, the second multi-layer structure comprising:
a second electrical structure spread across layers of the second multi-layer structure; and
one or more second exposed conductors on an exterior layer of the second multi-layer structure;
a conductive bonding agent coupling the one or more first exposed conductors to the one or more second exposed conductors such that the first electrical structure is electrically parallel to the first electrical structure; and
a material encapsulating the first multi-layer structure and the second multi-layer structure and flowing around the conductive bonding agent.

2. The circuit package of claim 1, wherein the first electrical structure is a first coupler.

3. The circuit package of claim 2, wherein the second electrical structure is a second coupler.

4. The circuit package of claim 3, wherein the first coupler and the second coupler being in parallel creates an effective impedance less than an impedance less than either coupler alone.

5. The circuit package of claim 3, further comprising a third multi-layer structure stacked on the second multi-layer structure, the third multi-layer structure comprising:
a third electrical structure spread across layers of the third multi-layer structure; and
one or more third exposed conductors on an exterior layer of the second multi-layer structure electrically coupled to at least one of the one or more second exposed conductors.

6. The circuit package of claim 1, further comprising an impedance-matching circuit electrically positioned between the first electrical structure and a power amplifier die.

7. The circuit package of claim 1, wherein the first multi-layer structure comprises a metalized laminate.

8. The circuit package of claim 1, wherein the first multi-layer structure comprises a structure selected from the group consisting of a low temperature co-fired ceramic structure, a high temperature co-fired ceramic structure, and an additive manufacturing structure.

9. A circuit package comprising:
a first die comprising a first coupler and one or more exposed first connections;
a second die comprising a second coupler and one or more exposed second connections, the second die stacked on the first die; and
an electrical connection between the one or more exposed first connections and the one or more exposed second connections.

10. The circuit package of claim 9, further comprising a power amplifier positioned in the first die.

11. The circuit package of claim 9, wherein the first coupler is electrically parallel to the second coupler.

12. A method of making a package, comprising:
forming a multi-layer metalized laminate having a plurality of electrical structures formed across multiple layers of the multi-layer metalized laminate;
singulating the multi-layer metalized laminate into sub-sheets;
stacking a first sub-sheet onto a second sub-sheet;
electrically coupling electrical structures in the first sub-sheet to electrical structures in the second sub-sheet in parallel;
encapsulating the sub-sheets in a mold material; and
singulating the sub-sheets into parallel structure packages.

13. The method of claim 12, wherein the electrical structures comprise couplers.

14. The method of claim 12, wherein encapsulating the sub-sheets in the mold material comprises flowing mold in and around solder connections between the first sub-sheet and the second sub-sheet.

15. The method of claim 12, further comprising coupling at least one parallel structure package to an amplifier die.

16. The method of claim 15, further comprising coupling the at least one parallel structure package to the amplifier die through an impedance-matching circuit.

17. The method of claim 16, further comprising encapsulating the amplifier die, the impedance-matching circuit, and the at least one parallel structure package with a mold material.

18. The method of claim 12, further comprising testing the electrical structures in the sub-sheets.
